(19) United States
(12) Patent Application Publication
(10) Pub. No.: US 2026/0282423 A1
(43) Pub. Date: Sep. 17, 2026

(54) 2D VAN DER WAALS TRANSISTORS GATED WITH SPIN CROSSOVER/FERROELECTRIC LAYERS FOR MEMORY APPLICATIONS

(71) Applicants: BOARD OF REGENTS OF THE UNIVERSITY OF NEBRASKA, Lincoln, NE (US); THE TRUSTEES OF INDIANA UNIVERSITY, Bloomington, IN (US)

(72) Inventors: Ruihua Cheng, Carmel, IN (US); Peter A. Dowben, Crete, NE (US); Mohammed Zaid Zaz, Lincoln, NE (US); Saeed Yazdani, Austin, TX (US); Jared Phillips, West Palm Beach, FL (US)

(21) Appl. No.: 19/566,516

(22) Filed: Mar. 13, 2026

Related U.S. Application Data
(60) Provisional application No. 63/771,965, filed on Mar. 14, 2025.

(51) Int. Cl. H10D 30/47; G11C 11/16; G11C 11/22; H10B 51/30; H10B 61/00; H10D 30/69; H10D 62/80; H10N 50/20

(52) U.S. Cl. CPC H10D 30/481; G11C 11/1673; G11C 11/1675; G11C 11/2273; G11C 11/2275; H10B 51/30; H10B 61/22; H10D 30/701; H10D 62/882; H10D 62/883; H10N 50/20; G11C 11/223

(57) ABSTRACT

Van der Waals transistors gated with spin crossover/ferroelectric layers for memory applications are described. In certain embodiments, the transistors include a van der Waals material adjacent to a spin crossover molecular material, which is adjacent to a ferroelectric layer. In some embodiments, the van der Waals transistors are used for a thin film molecular memory that satisfies the criteria needed to make a molecular spintronic device, based on spin crossover complexes, competitive with silicon technology. In certain embodiments, the 2D material layer and the spin crossover molecular layer are a heterostructure that reduces impedance compared to a similar memory device lacking the 2D material layer.

### CROSS-REFERENCE TO RELATED APPLICATIONS

This application claims the benefit of U.S. Provisional Patent Application No. 63/771,965, filed Mar. 14, 2025, which is incorporated herein by reference in its entirety.

### GOVERNMENT SUPPORT

This invention was made with government support under Award No. DMR-2317464 awarded by the National Science Foundation. The Government has certain rights in this invention.

### BACKGROUND

The design of flexible and high-density nonvolatile memory devices remains an area of interest for obtaining high-speed memory devices. Organic electronics is one area of research. Organic electronics involve polymers, small molecules, and other forms of organic materials that are used for optoelectronic and electronic functionalities. By leveraging the intrinsic spin of electrons and associated magnetic moments of these organic materials, it is possible to create spintronic/magnetoelectronic devices. The voltage control of the magnetic states of these organic materials enables nonvolatile device elements whose state may be switched without large current densities and power consumption.

Accordingly, there is a need in the art for molecular systems to deliver low-power, nonvolatile magnetoelectric memory operations while lowering impedance issues present when using a ferroelectric layer adjacent to a spin crossover layer.

### BRIEF SUMMARY

Two dimensional (2D) van der Waals transistors gated with spin crossover/ferroelectric layers for memory applications are described. The inclusion of the van der Waals material adjacent to a spin crossover molecular material, which is adjacent to a ferroelectric layer creates a heterostructure as the gate material. The heterostructure allows for room temperature isothermal switching with reduced impedance compared to a similar transistor lacking the 2D material. In some embodiments, a thin film molecular memory is formed. The thin film molecular memory is a non-volatile heterostructure of spin crossover molecules with a 2D material to form a memory element compatible with back end of line (BEOL) silicon processing and can be used as cache memory as well as a replacement for flash memory and transistors in flexible displays. The thin film molecular memory uses voltage controlled molecular spin state switching.

In some aspects, a system includes: a circuit substrate; and a thin film molecular memory deposited on the circuit substrate, wherein the thin film molecular memory includes a non-volatile 2D and molecular thin film memory element, formed of a 2D material layer adjacent to a spin crossover molecular layer, which is adjacent to a ferroelectric layer. In some embodiments, the 2D material layer is a van der Waals material. In certain embodiments, the 2D material layer forms a transistor channel for the thin film non-volatile 2D memory element, and the spin crossover molecular layer combined with the ferroelectric layer serves as the gate.

In some aspects, a memory device includes a 2D material layer adjacent to a spin crossover molecular layer, which is adjacent to a ferroelectric layer. In some embodiments, the memory device can be a four-terminal non-volatile 2D and molecular thin film memory element including a top gate adjacent to the 2D spin material layer and a bottom gate adjacent to the ferroelectric layer. A first of four terminals of the four-terminal non-volatile 2D and molecular thin film memory element connects to the top gate. A second of four terminals connects to a source. A third of the four terminals connects to a drain. A fourth of the four terminals connects to the bottom gate and a ground. In certain embodiments, the non-volatile 2D and molecular thin film memory element forms a thin film molecular memory device allowing for room temperature isothermal switching.

In some aspects, a method of operating a non-volatile 2D and molecular thin film memory element includes establishing a polarization state in a ferroelectric layer, wherein at least a portion of an electric field associated with the polarization state is transmitted through a 2D material layer to modulate a spin state of an adjacent spin crossover molecular layer; and detecting an electrical impedance corresponding to the spin state. In some embodiments, the method further includes reversing the polarization state to induce a second impedance state. In certain embodiments, detecting the electrical impedance includes applying a sense voltage lower in magnitude than a programming voltage.

This Summary is provided to introduce a selection of concepts, in a simplified form, that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1A shows a graph of the current-voltage, I(V), characteristics of a memory device without a 2D material layer, and FIG. 1B shows a graph of the current-voltage, I(V), characteristics of a similar device when a 2D material layer has been added.

FIG. 2A shows a schematic diagram of a non-volatile 2D and molecular thin film memory element gated with a combination of the spin crossover material thin film and ferroelectric thin film.

FIG. 2B and FIG. 2C show a circuit scheme for the non-volatile 2D memory element gated with spin crossover material and ferroelectrics of FIG. 2A.

FIG. 3A shows a schematic of an example non-volatile 2D memory and molecular thin film element cell consistent with FIG. 2A.

FIG. 3B shows a simplified schematic cross-section of the non-volatile 2D and molecular thin film memory element cell of FIG. 3A.

FIG. 4A shows a circuit diagram of a memory array with peripheral circuitry.

FIG. 4B shows a circuit diagram of an array level read operation using the non-volatile 2D memory element gated with the spin crossover/ferroelectric layer of FIG. 2A.

FIG. 5 shows a flowchart illustrating a method of using a non-volatile 2D memory element in accordance with the present disclosure.

### DETAILED DESCRIPTION

Two dimensional (2D) van der Waals transistors (non-volatile 2D memory elements) gated with a spin crossover/ferroelectric thin film heterostructure for memory applications are described. The non-volatile 2D and molecular thin film memory element can be referred to as a molecular multiferroic spin transistor. Transistor-like devices based on spin crossover molecular systems are used in memory devices, such as a thin film molecular memory. A thin film molecular memory is a nonvolatile memory compatible with back end of line (BEOL) silicon processing and can be used as cache memory as well as a replacement for flash memory and transistors in flexible displays. The thin film molecular memory uses voltage controlled molecular spin state switching. However, conventionally these memory devices have been plagued by high impedance of the voltage-controlled spin crossover transistors that are typically present in spin crossover molecular systems. In the present disclosure, high impedance issues are resolved by using a material stack in the following order: a ferroelectric material (FE), a spin crossover material (SCO), and a 2D material (2DM).

Manufacturing a non-volatile 2D and molecular thin film memory element having a 2D material layer adjacent to a spin crossover molecular layer, which is adjacent to a ferroelectric layer, leverages the laterally highly-conductive nature of the 2D material layer to provide a facile read mechanism for the non-volatile 2D and molecular thin film memory element. Functional properties of the spin crossover molecular material are strongly coupled with the transport properties of the 2D material layer. Inclusion of the 2D material layer overcomes high impedance issues by employing the ferroelectric/spin crossover heterostructure as the gate material. In some embodiments, the 2D material layer forms what functions analogously to a transistor channel for the non-volatile 2D and molecular thin film memory element, and the spin crossover molecular layer combined with the ferroelectric layer serves as the gate. The non-volatile 2D and molecular thin film memory element constructed with the 2D material layer adjacent to the spin crossover molecular layer allows for room temperature isothermal switching with reduced impedance compared to a spin crossover molecular memory element lacking the 2D material layer.

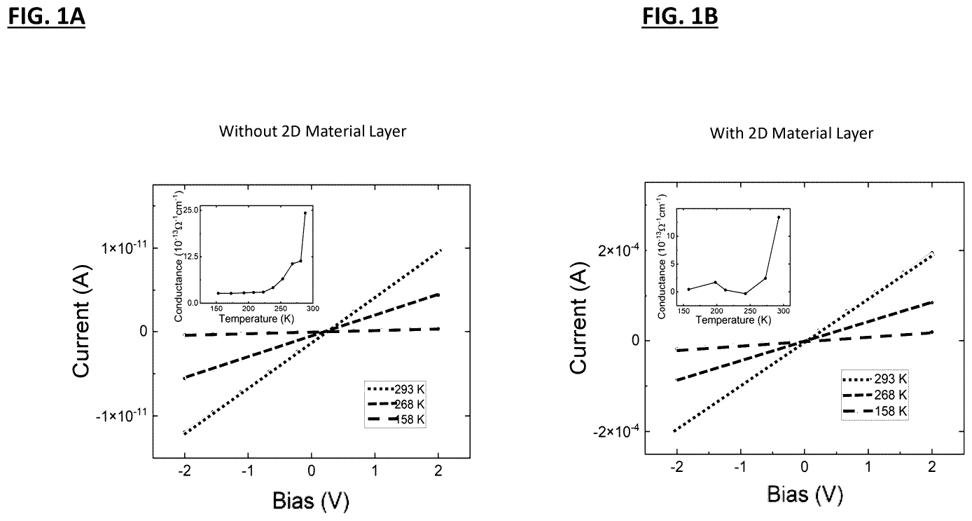

Specifically, as depicted in FIGS. 1A and 1B, it has been demonstrated that temperature-dependent current-voltage measurements in such elements show a massive conductivity change when a spin crossover layer is interfaced with a 2D material, which, in a specific experimental case, was Ti₃C₂, a known MXene. Without this 2D material, 200 nm thin films of [Fe{H₂B(pz)₂}₂(bipy)] films exhibited insulating-like current levels in the picoampere range, as shown in FIG. 1A. With Ti₃C₂ drop casted from solution, as the 2D material, onto the films, however, the current-voltage (I-V) measurements of the same 200 nm [Fe{H₂B(pz)₂}₂(bipy)] films showed a substantial increase in measured current across the same voltage and temperature ranges, as shown in FIG. 1B. Insets in each panel in FIGS. 1A and 1B show the extracted temperature-dependent conductance, demonstrating a significant enhancement in electrical transport following Ti₃C₂ incorporation while preserving temperature-dependent switching behavior near ~160 K. Note the temperature dependent switching is a stand-in for the voltage controlled switching, at and above room temperature, when interfaced with the ferroelectric and placed in the device geometry.

A thin film molecular memory is provided that satisfies the criteria needed to make a molecular spintronic device, based on spin crossover complexes, competitive with silicon technology. These criteria include device implementation, a low coercive voltage (less than 1 V) and low write peak currents (on the order of 105 A/cm²), a device on/off ratio >10, thin film quality, the ability to “lock” the spin state (providing nonvolatility), the ability to isothermally “unlock” and switch the spin state with voltage, conductance change with spin state, room temperature and above room temperature operation, an on-state device resistivity less than 1 Ω.cm, a device fast switching speed (less than 100 ps), device endurance (on the order of 10¹⁶ switches without degradation), and the ability of having a device with a transistor channel width of 10 nm or below. Collectively, these performance benchmarks position the thin film molecular memory formed using the non-volatile 2D and molecular thin film memory element of the present disclosure as a viable successor or complement to advanced CMOS nodes, particularly in applications demanding extreme scaling and energy efficiency.

A system can be fabricated that includes a circuit substrate and a thin film molecular memory, formed comprising non-volatile 2D and molecular thin film memory elements, deposited on the circuit substrate, which may occur in a back end of line process. In certain embodiments, the ferroelectric layer is fabricated by evaporation or Langmuir-Blodgett thin film growth. In some embodiments, the ferroelectric layer comprises an organic ferroelectric material. The thin film molecular memory is formed of a 2D material layer adjacent to a spin crossover molecular layer, which is adjacent to a ferroelectric layer. In certain embodiments, the 2D material layer is a van der Waals material. In some embodiments, the 2D material is graphene, MXene, or a chalcogenide such as a trichalcogenide or dichalcogenide. The circuit substrate itself can include transistor devices. In some cases, the non-volatile 2D and molecular thin film memory elements of the thin film molecular memory are electrically connected to the transistor devices of the circuit substrate through vias and metal lines in the circuit substrate. The transistor devices can include complementary metal oxide semiconductor (CMOS) transistors. In some implementations, the thin film molecular memory comprises a two-terminal diode non-volatile 2D and molecular thin film memory element. In some implementations, the thin film molecular memory comprises a four-terminal non-volatile 2D and molecular thin film memory element. Molecular thin films are easily fabricated and compatible with flexible substrates, making low-cost molecular solid-state memory with a large ON/OFF ratio achievable.

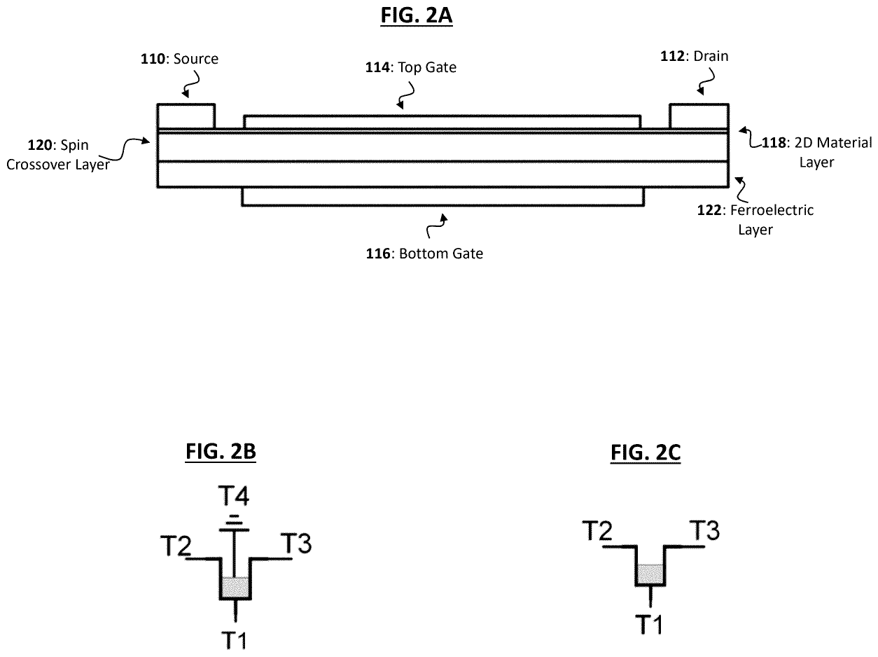

Regarding device implementation, FIG. 2A shows a schematic diagram of a non-volatile 2D and molecular thin film memory element gated with a spin crossover molecular layer 120 and ferroelectrics (e.g. a molecular multiferroic spin transistor). A source 110 and drain 112 with a top gate 114 sit on top of a 2D material layer 118. Directly adjacent to and below the 2D material layer 118 is the spin crossover molecular layer 120, which is adjacent to a ferroelectric (e.g., a polyvinylidene fluoride or PVDF) layer 122. The bottom gate 116 dielectric sits below and directly adjacent to the ferroelectric layer 122. Note that, for convenience in illustrating the structural relationships, FIG. 2A is not drawn to scale.

Appreciably in FIG. 2A, the ordering of the 2D material layer 118 and the spin crossover molecular layer 120 is significant and results in an improved 2D materials/spin crossover molecular heterostructure concept, which is applicable to molecular heterostructure capacitive device structures in general. In certain embodiments, the structure is polarizing toward a specific direction of ferroelectric that causes the spin crossover molecular layer 120 (e.g., SCO Fe(Htrz)₂(trz)BF₄) to switch to low spin (LS) and high spin (HS) states. In some embodiments, the electric field associated with the ferroelectric polarization penetrates the 2D material layer 118 (e.g., MXene Ti₃C₂ and other van der Waals materials). In certain embodiments, Fe{H2B(pz)₂}₂(bipy), Fe(phen)₂(NCS)₂, and Fe(Htrz)₂(trz)BF₄ can be used as the spin crossover material for the spin crossover molecular layer 120. It is contemplated and presently supported by experimentation that the ferroelectric polarization is not fully screened by the 2D material layer 118 and that planar conductance in the transistor channel (e.g., the 2D material layer with an assist from the spin crossover layer 118) is broadly affected by the spin state and by ferroelectric gate polarization.

FIG. 2B and FIG. 2C show a circuit scheme for the non-volatile 2D and molecular thin film memory element gated with spin crossover material and ferroelectrics of FIG. 2A. Specifically, FIG. 2B and FIG. 2C show a circuit scheme for a four-terminal non-volatile 2D and molecular thin film memory element having terminals: T1, T2, T3, and T4. T1, which is the first of four terminals, connects to top gate 114. T2, which is the second of four terminals, connects to source 110. T3, which is the third of four terminals, connects to drain 112. T4, which is the fourth of four terminals, connects to bottom gate 116 and to a ground. Because terminal T4 is connected to a ground, by convention, the ground is not always explicitly shown in a circuit scheme, which is reflected in FIG. 2C. Although FIGS. 2B and 2C illustrate a four-terminal non-volatile 2D and molecular thin film memory element, the disclosure is not limited in this regard. For example, two-terminal non-volatile 2D and molecular thin film memory elements gated with spin crossover material and ferroelectrics are contemplated.

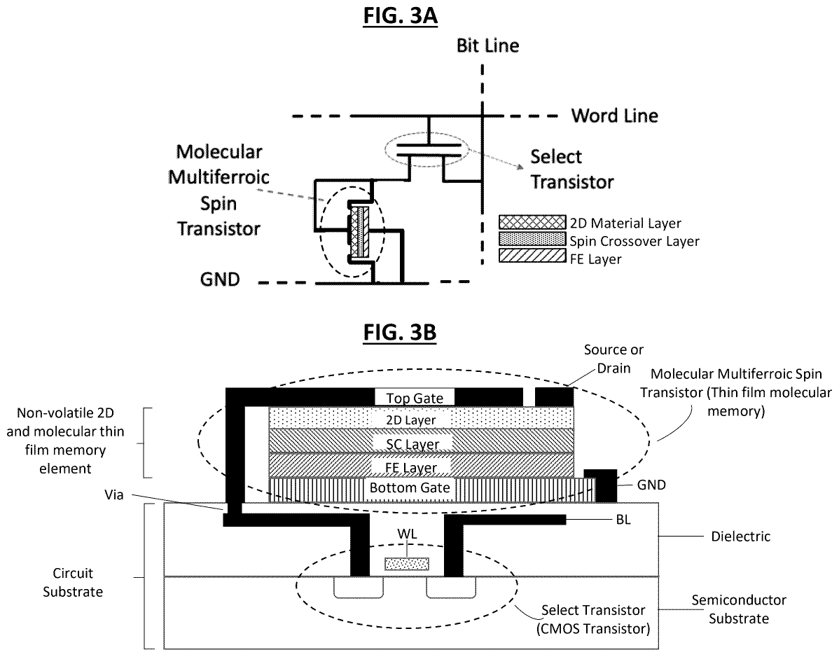

FIG. 3A shows a schematic of an example non-volatile 2D and molecular thin film memory element cell consistent with FIG. 2A. FIG. 3B shows a simplified schematic cross-section of the non-volatile 2D and molecular thin film memory element of FIG. 3A. The non-volatile 2D and molecular thin film memory element of FIG. 3B can be formed through back end of line (BEOL) silicon processing. FIG. 3B expressly shows the circuit substrate, the non-volatile 2D and molecular thin film memory element, as well as the molecular multiferroic spin transistor and a select transistor. The molecular multiferroic spin transistor is shown with a top gate, an adjacent 2D material layer (e.g., 2D layer), which is adjacent to a spin crossover molecular layer (e.g., SC layer), which is adjacent to the ferroelectric layer (e.g., FE layer), which is adjacent to the bottom gate. The bottom gate and a portion of the 2D layer that serves as a drain contact are connected to a ground (e.g., GND). A bit line (BL) and a word line (WL) for selecting the molecular multiferroic spin transistor are shown in FIGS. 3A and 3B.

The non-volatile 2D and molecular thin film memory element cell of FIGS. 3A and 3B is based on the design of a field effect voltage-controlled spin state molecular transistor and can exploit the differential between the low-resistance and high-resistance states of the 2D and molecular thin film material layer in a voltage-controlled spin state molecular memory device fabricated from spin crossover complexes. However, unlike DRAM (dynamic random-access memory), where charge storage on a capacitor must be refreshed periodically, molecular spin state memory is non-volatile and the stored state is represented by distinct electrical resistance states. This is particularly useful when low-power memory is needed.

It should be understood that this non-volatile 2D and molecular thin film memory element is not the only implementation scheme for nonvolatile spin crossover molecular devices.

It is possible to achieve a low coercive voltage (less than 1V) and low write peak currents (on the order of 10⁵ A/cm²) through the use of a thin ferroelectric layer adjacent to the spin crossover molecular layer. Indeed, molecular ferroelectric gate dielectrics can be made as thin as 1 nm and still be reliable, in which case the coercive voltage would be <0.5 V. An organic ferroelectric gate dielectric having a thickness of approximately 2 nm thick can provide reliable operation given a coercive voltage of about 0.8 V or less. Accordingly, a thin film molecular memory can be formed of a ferroelectric layer with a thickness of less than 5 nm adjacent to a spin crossover molecular layer, as illustrated in FIG. 3B (not to scale). Higher write speeds generally require higher peak current densities to generate the electric field needed to switch the polarization of the ferroelectric layer at the gate, although there are write speed gains to be had by decreasing the ferroelectric film thickness (which is further desirable also because of the commensurately smaller coercive voltage). There is a trade-off between faster write speeds and lower peak current densities for a ‘write’ operation. Engineering the ferroelectric thickness and crystallinity enables optimization of switching energy while preserving long-term reliability.

In detail, working non-volatile 2D and molecular thin film memory elements make use of a ferroelectric layer adjacent to the spin crossover molecular layer. Thus, the coercive voltage of the device tends to be dominated by the coercive voltage of the ferroelectric layer. The choice of molecular ferroelectric also plays a role. Material selection influences not only coercive voltage but also polarization stability, fatigue resistance, and interfacial dipole strength. Consequently, predictable and repeatable device behavior can be achieved through judicious pairing of ferroelectric and spin crossover molecules.

In some cases, the ferroelectric layer is formed of dipolar molecular additives. In some cases, the ferroelectric layer is formed of organic ferroelectric material. In some cases, the ferroelectric layer comprises benzimidazole, 2-methylbenzimidazole, 5,6-dichloro-2-methylbenzimidazole, bridged bis(benzimidazole), croconic acid, or a copolymer of polyvinylidene fluoride. These molecular ferroelectrics offer advantages such as mechanical flexibility, low-temperature processing, and chemical tunability, enabling precise adjustment of polarization magnitude and switching thresholds.

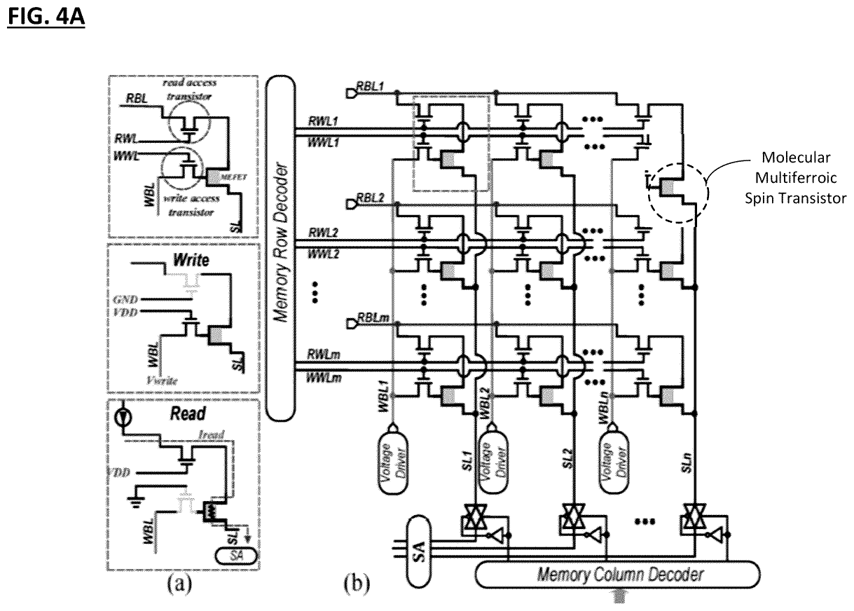

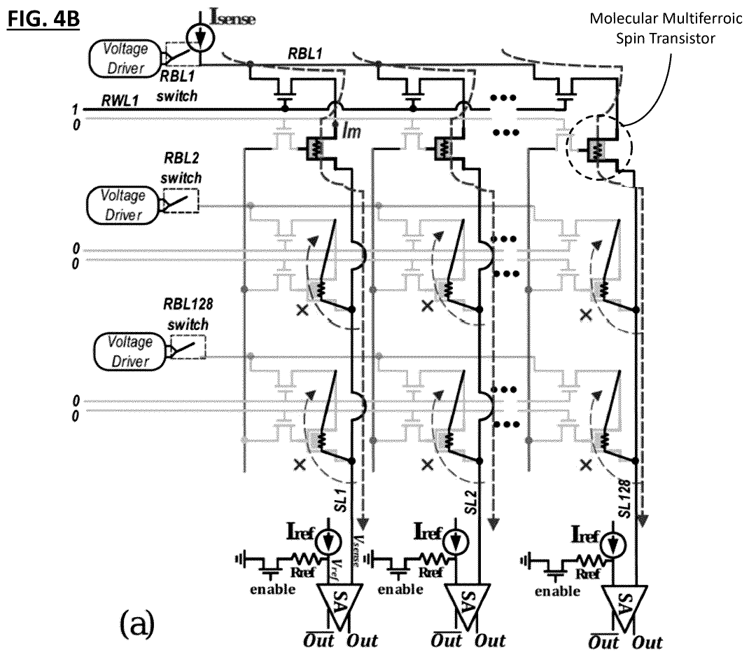

FIG. 4A shows a circuit diagram of a memory array with peripheral circuitry. The array includes a set of non-volatile 2D and molecular thin film memory elements, such as shown in FIG. 2A. In section (a) of FIG. 4A, a memory bit cell with read and write signals is shown. In section (b), an m×N memory array with peripheral devices is illustrated. Different circuits can utilize the non-volatile 2D and molecular thin film memory element and system detailed herein, and arrays deviating from that shown in FIG. 4A (and FIG. 4B) are contemplated.

By virtue of the four terminal structure (three terminals shown consistent with FIG. 2C as the T4 terminal is connected to ground), a memory bit-cell is described that has separate read and write paths, which facilitates independent optimization of both operations as well as avoiding common read-write conflicts. Each memory cell is controlled by five controlling signals (e.g., write word line (WWL), write bit line (WBL), read word line (RWL), read bit line (RBL), and source line (SL). The read/write access transistor is controlled by RWL/WWL enabling selective read/write operation on the cells located within one row. The write bit lines and read bit lines are shared among cells within the same row and write bit lines, while source lines are shared between cells in the same column. The write bit lines are controlled by the memory row decoder (active-high output). The column decoder (active-high output) controls the activation of the read current path through the source line. The voltage driver component is designed to set the proper voltage on the write bit line.

FIG. 4B shows a circuit diagram of an array-level read operation using the non-volatile 2D and molecular thin film memory elements gated with the spin crossover/ferroelectric layers of FIG. 2A, which may be termed molecular multiferroic spin transistors. In FIG. 4B, a read operation senses the resistance of a selected non-volatile 2D and molecular thin film memory element cell and compares this resistance using a Sense Amplifier (SA). At the array level, row and column decoders activate the read word line (RWL) and source line (SL) paths, respectively. When a non-volatile 2D and molecular thin film memory element cell is selected by applying a very small sense current (sub-microamp) to the read bit line (RBL), a voltage (Vₛₑₙₛₑ) is generated on the corresponding SL, which is taken as the input of the sense current. Owing to a low or high resistance state of the selected cell, the sense voltage will be V_{low} or V_{high} (V_{low}<V_{high}), respectively. Thus, through setting the reference voltage at (V_{low}+V_{high})/2, the SA outputs binary “1” when Vₛₑₙₛₑ>V_{ref}, whereas the output is “0” when Vₛₑₙₛₑ<V_{ref}. Each read operation of FIG. 4B requires two clock phases: a pre-charge phase (CLK “high”), in which the sense amplifier is reset to a known state, and a sensing phase (CLK “low”), in which a small voltage difference between Vₛₑₙₛₑ and V_{ref} produces a current imbalance in the input transistors. This imbalance is amplified by the cross-coupled inverter latch, causing the sense amplifier to resolve to a digital logic level corresponding to the stored resistance state.

Write operations using the logic design of FIGS. 4A and 4B can be accomplished by activating the word write line (WWL) and asserting appropriate bipolar write voltage (V_{write}/−V_{write}) through a voltage driver on the word bit line (WBL). The voltage provides adequate vertical electrical field strength across the ferroelectric layer to switch the ferroelectric polarization. This in turn switches the spin state of the underlying spin crossover molecular layer to affect a change in the electrical transport of the adjacent 2D material layer. Unaccessed rows are isolated by driving corresponding write lines to ground by a row decoder, not shown. This avoids unwanted current paths that potentially cause false write/read states.

Generally, FIGS. 4A and 4B provide one contemplated logic design for the 2D memory element of FIG. 2A and its peripheral circuitry; however, the disclosure is not limited in this regard.

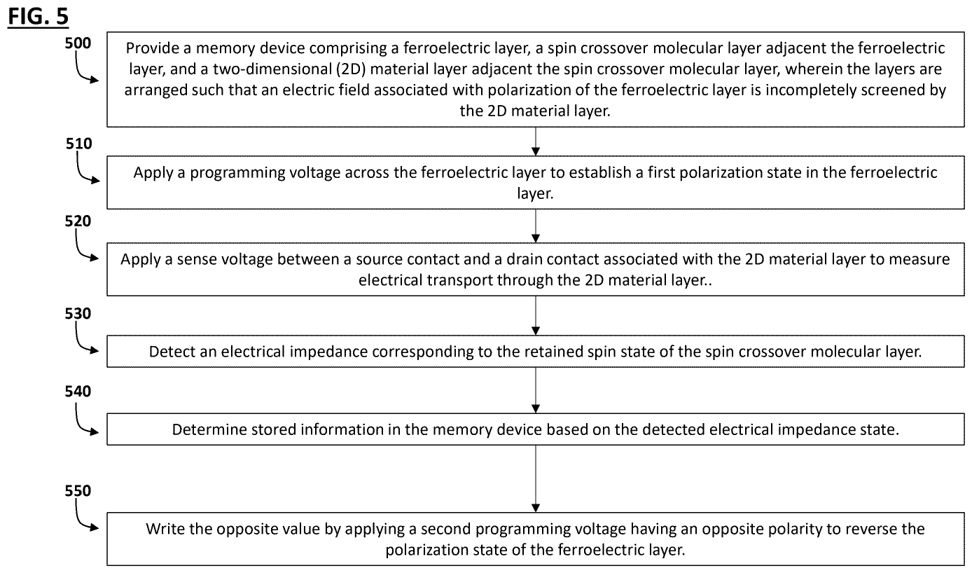

FIG. 5 shows a flowchart illustrating a method of using a non-volatile 2D and molecular thin film memory element in accordance with the present disclosure. The method includes providing a non-volatile 2D and molecular thin film memory element comprising a ferroelectric layer, a spin crossover molecular layer adjacent the ferroelectric layer, and a two-dimensional (2D) material layer adjacent the spin crossover molecular layer, wherein the layers are arranged such that an electric field associated with polarization of the ferroelectric layer is incompletely screened by the 2D material layer.

In certain embodiments, a non-volatile 2D and molecular thin film memory element having the ferroelectric layer, the spin crossover molecular layer, and the 2D material layer is provided (500). In certain embodiments, the 2D material layer forms a conductive channel between a source contact and a drain contact, while the ferroelectric layer and the spin crossover molecular layer collectively function as a gate structure for modulating electrical transport through the 2D material layer.

In embodiments, a programming voltage is applied across the ferroelectric layer to establish a first polarization state in the ferroelectric layer (510). The polarization state produces an electric field extending from the ferroelectric layer toward the adjacent layers of the device. The electric field associated with the polarization state penetrates the 2D material layer and interacts with the adjacent spin crossover molecular layer. Because the electric field is incompletely screened by the 2D material layer, the electric field influences the electronic configuration of the spin crossover molecular layer. The spin crossover molecular layer transitions to a corresponding spin state in response to the electric field associated with the polarization state of the ferroelectric layer. In certain embodiments, the spin crossover molecular layer transitions between a low-spin state and a high-spin state. The polarization state of the ferroelectric layer is retained after removal of the programming voltage such that the spin state of the spin crossover molecular layer is retained, thereby defining a corresponding electrical impedance state of the non-volatile 2D and molecular thin film memory element.

In embodiments, a sense voltage (520) is applied between the source contact and the drain contact associated with the 2D material layer to measure electrical transport through the 2D material layer of the non-volatile 2D memory element.

In embodiments, an electrical impedance corresponding to the retained spin state of the spin crossover molecular layer is detected (530) through the electrical transport characteristics of the 2D material layer.

In embodiments, stored information represented by the non-volatile 2D and molecular thin film memory element is determined (540) based on the detected electrical impedance state.

In embodiments wherein the non-volatile 2D and molecular thin film memory device is written to the opposite value, a second programming voltage having an opposite polarity is applied (550) across the ferroelectric layer to reverse the polarization state of the ferroelectric layer. The reversed polarization state induces a second spin state in the spin crossover molecular layer, thereby defining a second electrical impedance state of the memory device corresponding to a different stored information state.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims, and other equivalent features and acts are intended to be within the scope of the claims.

As used herein, “non-volatile 2D and molecular thin film memory element” refers to a memory device comprising a two-dimensional (2D) material layer functioning as a conductive channel and a spin crossover molecular layer coupled to a ferroelectric layer, wherein polarization of the ferroelectric layer modulates a spin state of the spin crossover molecular layer and thereby alters electrical transport through the 2D material layer. The device retains a selected electrical impedance state corresponding to the spin state after removal of a programming voltage, thereby enabling storage of information without continuous power. The 2D material layer may comprise a van der Waals material and may provide an in-plane conductive pathway between electrical contacts used to read the stored state.

As used herein, “ferroelectric layer” refers to a material layer exhibiting switchable spontaneous electric polarization that can be reversed by application of an external electric field and that retains the polarization state after removal of the external field.

As used herein, “polarization” refers to a stable orientation of electric dipoles within a ferroelectric material that produces an associated electric field extending beyond the ferroelectric material.

As used herein, “spin crossover molecular layer” refers to a layer comprising molecules capable of reversible transition between at least two electronic spin states that differ in magnetic, electronic, structural, or transport properties.

As used herein, “spin state” refers to a molecular electronic configuration characterized by a specific total electron spin, including at least a low-spin state and a high-spin state.

As used herein, “electrical impedance state” refers to an electrical condition of a device or layer characterized by a measurable impedance value, including resistance, capacitance, reactance, or combinations thereof.

As used herein, “programming voltage” refers to a voltage applied to establish or alter a polarization state of a ferroelectric layer or otherwise modify the stored state of a memory device.

As used herein, “sense voltage” refers to a voltage applied for measurement of a stored state that is insufficient to alter the polarization state of a ferroelectric layer or the spin state of a spin crossover molecular layer.

As used herein, “two-dimensional material layer” or “2D material layer” refers to a material layer having a thickness of one or a few atomic layers and exhibiting in-plane electrical conductivity.

As used herein, “two-dimensional material” refers to a material having a layered structure in which charge transport occurs primarily within a plane of atomic-scale thickness, including graphene, MXenes, transition metal dichalcogenides, and related van der Waals materials.

As used herein, “van der Waals material” refers to a material composed of atomically thin layers that are held together primarily by van der Waals interactions rather than covalent bonds between adjacent layers.

As used herein, “MXene” refers to a class of two-dimensional transition metal carbides, nitrides, or carbonitrides derived from layered MAX phases and having a general formula Mₙ₊₁XₙTx, where M is a transition metal, X is carbon or nitrogen, and Tx represents surface terminations.

As used herein, “chalcogenide” refers to a compound comprising at least one chalcogen element selected from sulfur, selenium, or tellurium combined with a metal or semimetal.

As used herein, “incompletely screened electric field” refers to an electric field that is partially transmitted through a conductive or semiconductive layer rather than being fully neutralized by mobile charge carriers.

As used herein, “transistor channel” refers to a conductive pathway whose electrical conductivity is modulated by an external electric field or by a change in the electronic or spin state of an adjacent material. The term is not limited to a semiconductor inversion layer, depletion region, or accumulation layer formed in a semiconductor substrate, and does not require operation according to conventional semiconductor field-effect transistor physics. In embodiments of the present disclosure, the transistor channel may comprise a two-dimensional conductive material whose conductivity is modulated by polarization of an adjacent ferroelectric layer and/or a spin-state transition in an adjacent spin crossover molecular layer.

As used herein, “gate structure” refers to an electrode or electrode assembly configured to apply an electric field that modulates the conductivity of a “transistor channel.”

As used herein, “room temperature isothermal switching” refers to switching between device states at substantially constant temperature within a range of approximately −75° C. to 100° C.

As used herein, “circuit substrate” refers to a charge compensated semiconductor and/or dielectric substrate containing active electronic devices and associated interconnect structures.

As used herein, “back-end-of-line process” refers to fabrication steps performed after formation of active devices in a circuit substrate.

As used herein, “molecular multiferroic spin transistor” refers to a multi-terminal electronic device comprising a spin crossover molecular layer and a ferroelectric layer coupled to a conductive channel, wherein polarization of the ferroelectric layer modulates a spin state of the spin crossover molecular layer and thereby alters electrical transport in the conductive channel between a source terminal and a drain terminal. The conductive channel may comprise a two-dimensional material layer, and the device operates such that the spin-state-dependent change in electrical transport corresponds to at least two distinguishable electrical states representing stored information. The term does not require operation according to the physics of a conventional semiconductor field-effect transistor and encompasses devices in which gate-induced ferroelectric polarization controls spin-dependent transport in a molecular heterostructure.

What is claimed is:

1. A system, comprising:
a circuit substrate; and
a thin film molecular memory deposited on the circuit substrate, wherein the thin film molecular memory comprises a 2D and molecular thin film memory element formed of a 2D material layer adjacent to a spin crossover molecular layer, which is adjacent to a ferroelectric layer.

2. The system of claim 1, wherein the 2D material layer is a van der Waals material.

3. The system of claim 1, wherein inclusion of the 2D material layer reduces impedance compared to a system where the thin film molecular memory lacks the 2D material layer.

4. The system of claim 1, wherein the 2D material layer forms a transistor channel for the thin film molecular memory.

5. The system of claim 1, wherein the 2D and molecular thin film memory element is a four-terminal 2D and molecular thin film memory element.

6. The system of claim 1, wherein the thin film molecular memory is deposited in a back end of line process.

7. The system of claim 1, wherein the circuit substrate comprises a transistor device.

8. The system of claim 7, wherein the 2D and molecular thin film memory element of the thin film molecular memory is provided in plurality, wherein a plurality of the 2D and molecular thin film memory elements is electrically connected to a plurality of the transistor device of the circuit substrate.

9. The system of claim 8, wherein the plurality of 2D and molecular thin film memory elements is electrically connected to the plurality of transistor devices of the circuit substrate through vias and metal lines in the circuit substrate.

10. The system of claim 7, wherein the transistor device comprises a complementary metal oxide semiconductor (CMOS) transistor.

11. A 2D and molecular thin film memory element comprising:
a ferroelectric layer;
a spin crossover molecular layer adjacent to the ferroelectric layer; and
a 2D material layer adjacent to the spin crossover molecular layer.

12. The 2D and molecular thin film memory element of claim 11, wherein the 2D material layer is a van der Waals material.

13. The 2D and molecular thin film memory element of claim 11, wherein the 2D material layer comprises at least one of graphene, MXene, and a chalcogenide.

14. The 2D and molecular thin film memory element of claim 11, wherein the 2D material layer forms a transistor channel for the 2D and molecular thin film memory element.

15. The 2D and molecular thin film memory element of claim 11, wherein the 2D and molecular thin film memory element is a four-terminal 2D and molecular thin film memory element, comprising:
a top gate adjacent to the 2D material layer;
a bottom gate adjacent to the ferroelectric layer;
a source contact to the 2D material layer; and
a drain contact to the 2D material layer.

16. The 2D and molecular thin film memory element of claim 11, wherein the 2D and molecular thin film memory element is a four-terminal 2D and molecular thin film memory element, comprising:
a top gate adjacent to the ferroelectric layer;
a bottom gate adjacent to the 2D material layer;
a source contact to the 2D material layer; and
a drain contact to the 2D material layer.

17. The 2D and molecular thin film memory element of claim 11, wherein the ferroelectric layer, 2D material layer, and spin crossover molecular layer are selected and arranged such that polarization of the ferroelectric layer induces an electric field component that is incompletely screened by the 2D material layer and modulates a spin state of the spin crossover molecular layer, wherein the spin state defines at least two distinct electrical impedance states retained after removal of a programming voltage.

18. A method of operating a nonvolatile 2D and molecular thin film memory element comprising:
establishing a polarization state in a ferroelectric layer, wherein at least a portion of an electric field associated with the polarization state is transmitted through a 2D material layer to modulate a spin state of an adjacent spin crossover molecular layer; and
detecting an electrical impedance corresponding to the spin state.

19. The method of claim 18, further comprising reversing the polarization state to induce a second impedance state.

20. The method of claim 18, wherein detecting the electrical impedance comprises applying a sense voltage lower in magnitude than a programming voltage.
